(19) United States
(12) Patent Application Publication
(10) Pub. No.: US 2010/0200049 A1
(43) Pub. Date: Aug. 12, 2010

(54) BIOHYBRID SYSTEM FOR HYDROGEN PRODUCTION

(75) Inventors: Galyna Kufryk, Tempe, AZ (US); Maria Lucia Ghirardi, Golden, CO (US); Michael Hambourger, Teme, AZ (US); Thomas A. Moore, Tempe, AZ (US); Petra Fromme, Tempe, AZ (US)

Correspondence Address: PAUL J WHITE, PATENT COUNSEL;NATIONAL RENEWABLE ENERGY LABORATORY (NREL), 1617 COLE BOULEVARD, MS 1734, GOLDEN, CO, 80401-3393, US

(73) Assignee: Alliance for Sustainable Energy, LLC, Golden, CO (US)

(21) Appl. No.: 12/540,149

(22) Filed: Aug. 12, 2009

Related U.S. Application Data
(60) Provisional application No. 61/088,312, filed on Aug. 12, 2008.

(51) Int. Cl. H01L 31/00; C01B 3/02; B01J 19/08

(52) U.S. Cl. 136/252; 204/157.52; 422/186

(57) ABSTRACT

Provided herein are systems and methods for generating photocurrent and systems and methods for generating hydrogen. The systems comprise (a) isolated biological photosystem II (PSII) complexes; (b) an anode selected from the group consisting of graphite anode, glassy carbon anode, and FTO anode, wherein the PSII complexes are deposited onto the anode; (c) a source of red or white light, wherein red or white light illumination of the PSII complexes deposited on the anode generates a photoresponse comprising a photocurrent; (d) a working solution; and (e) a cathode. The methods comprise (a) isolating biological photosystem II (PSII) complexes; (b) providing an anode selected from the group consisting of a graphite anode, a glassy carbon anode, and an FTO anode, wherein the PSII complexes are deposited onto the anode; (c) providing a working solution; (d) providing a cathode; and (e) illuminating with red or white light the PSII complexes deposited on the anode, wherein red or white light illumination of PS II complexes generates a photoresponse comprising a photocurrent.

### CROSS-REFERENCE TO RELATED APPLICATIONS

This application claims priority to U.S. Provisional Application No. 61/088,312, filed Aug. 12, 2008, the contents of which are incorporated by reference in their entirety.

### CONTRACTUAL ORIGIN

The United States Government has rights in this invention under Contract No. DE-AC36-08G028308 between the United States Department of Energy and the Alliance for Sustainable Energy, LLC, manager and operator of the National Renewable Energy Laboratory.

### BACKGROUND

Increases in projected energy demand in conjunction with a decrease in fossil fuel reserves and the drive to reduce CO₂ emissions is stimulating the development of clean renewable energy technologies. Such clean technologies include wind, photovoltaics, solar, thermal, geothermal, hydroelectric, and biofuels. Biofuels encompass bioethanol, biodiesels, and biohydrogen. Among the many promising technologies is photobiological production of hydrogen by prokaryotic or eukaryotic organisms, which has the potential to generate renewable hydrogen fuel from light and water, which are among nature's most plentiful resources.

Biohybrid systems for hydrogen production have been actively explored for the past two decades. Typically, they make use of the redox properties of the photosynthetic units of living organisms, mostly photosystem II (PS II) as well as photosystem I (PS I). Photosystems are deposited onto an electrode conducting surface that acts as an anode. The anode is then connected to a cathode on which hydrogen is produced. Sunlight is typically the source of energy in these systems as both PS II and PS I have the capacity to absorb photons and convert their energy into energy of separated charges. The separated charges are further used for redox reactions involving these complexes.

PS II is a well-studied pigment-protein complex present in photosynthetic organisms that is capable of using sunlight to oxidize water and reduce plastoquinone molecules. PS II is the only known enzyme that performs light-driven water oxidation at ambient temperature and atmospheric pressure. Naturally, water oxidation at these conditions is an inexpensive means of producing oxygen and, potentially, hydrogen as well. Hydrogen production can be achieved when electrons that are released during water oxidation are used to reduce protons to molecular H₂ by a hydrogenase or nitrogenase enzyme, or by an alternate catalyst (such as Pt), in vitro.

The development of electrochemical systems involving biological PS II has been attempted in the past, using PSII from various species of photosynthetic organisms combined with various types of electrode surfaces. Rao et al. (1990) mention a PS II electrode based on dye-derivatized crystalline TiO₂, covered with PS II from spinach and using 300 μM 2,6-dichloro-p-benzoquinone (DCBM), dissolved in a working solution, as an electron acceptor. This electrode, wired to a platinum cathode and a saturated calomel electrode as a reference electrode, was capable of generating a photocurrent of up to 35 μA cm⁻² upon irradiation with white light and an applied potential of 0.2V versus the saturated calomel electrode. It was estimated that about 20% of the PS II centers in solution contributed to the observed photocurrent. The maximum monochromatic incident-photon to current conversion efficiency of this system was 12% for the light with a wavelength of 520 nm, and the working half-time of the electrode as measured by decrease of photocurrent amplitude over time, was 75 min (Rao, K. K., D. O. Hall, N. Vlashopoulos, M. Gratzel, M. C. W. Ewans, and M. Seibert. (1990) Photochemical responses of photosystem II particles immobilized on dye-derivatized TiO₂ films. Journal of Photochemistry and Photobiology. 5: 379-389.).

Amako et al. (1993) mention spinach PSII membranes deposited on a carbon paste electrode in which carbon paste was mixed with an artificial electron acceptor, 2,6-dimethylbenzoquinone (DMBQ). The photocurrent generated by this electrode had the maximum amplitude at a 0.55V potential versus an Ag/AgCl electrode, and was proportional to the amount of PS II deposited onto the electrode in a range of 0.5-2.5 μg chlorophyll; further increases in the amount of PS II resulted in a lower photocurrent amplitude, since increasing the thickness of the PS II layer resulted in shading of a portion of the PS II centers. The maximum oxygen evolution rate of the PS II centers deposited onto the electrode was only one-third of the rate in solution, so that the electrode had a lower water splitting efficiency than free PS II (Amako, K., H. Yanai, and T. Ikeda. (1993) Dimethylbenzoquinone-mediated photoelectrochemical oxidation of water at a carbon paste electrode coated with photosystem II membranes. Journal of Electroanalytical Chemistry. 362: 71-77.).

Maly et al. (2005) used both wild type and recombinant PS II isolated from thermophilic cyanobacteria (Synechococcus bigranulatus and Synechococcus elongatus, respectively) deposited onto a gold electrode that was chemically modified to either bind his-tagged PS II particles or to provide a conductive layer of poly-mercapto-p-benzoquinone that facilitates electron transport from the PSII to the electrode. These electrodes allowed for controlled formation of a PS II monolayer on their surface and provided a higher density of photocurrent but were not stable (a half-life of about 1-3 hours due to the PS II degradation under experimental conditions (Maly, J., J. Krejci, M. Ilie, L. Jacubka, J. Masojidek, R. Pilloton, K, Sameh, P. Steffan, Z. Stryhal, and M. Sugiura. (2005) Monolayers of photosystem II on gold electrodes with enhanced sensor response—effect of porosity and protein layer arrangement. Anal. Bioanal. Chem. 381: 1558-1567; Maly, J., J. Masojidek, A. Masci, M. Ilie, E. Cianci, V. Foglietti, W. Vastarella, and R. Pilloton. (2005). Direct mediatorless electron transport between the monolayer of photosystem II and poly (mercapto-p-benzoquinone) modified gold electrode—new design of biosensor for herbicide detection. Biosensors and Bioelectronics. 21:923-932.)).

A similar approach was used by Badura et al. (2006) to create a PS II electrode using his-tagged PS II from Thermosynechococcus elongatus that was attached to a gold electrode modified with thiolates and bearing terminal Ni(II)-nitriloacetate groups. A high density of recombinant protein was deposited onto the electrode (0.29 pmol cm ⁻²). When used with DCBQ as electron acceptor and an applied oxidation potential of 0.3V, this electrode produced a photocurrent density of up to 14 μA cm⁻², and demonstrated an action spectrum similar to that of PS II. The latter proved that the photocurrent did indeed originate from the PS II complexes deposited onto the electrode (Badura, A., B. Esper, K. Ataka, C. Grunwald, C. Wöll, J. Kuhlmann, J. Heberle, and M. Rogner. (2006) Light-driven water splitting for (bio-) hydrogen production: photosystem 2 as the central part of a bioelectrochemical device. Photochemistry and Photobiology. 82: 1385-1390.). The authors did not report the working lifetime of this electrode but since the material of electrode and principle of PS II deposition on the surface are the same as in earlier experiments of Maly et al. (2005), the expected half-life of the device should be around 1 to 3 hours.

The short working lifetime of the electrode remains a major obstacle in creating a reliable system for electrochemical production of hydrogen using the water-oxidizing capacity of PS II. Another important aspect of the problem is choice of material for the electrode that would be a less expensive alternative to gold.

The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods which are meant to be exemplary and illustrative, not limiting in scope. In various embodiments, one or more of the above-described problems have been reduced or eliminated, while other embodiments are directed to other improvements.

Embodiments herein provide a system for generating photocurrent comprising: (a) isolated biological photosystem II (PSII) complexes; (b) an anode selected from the group consisting of graphite anode, glassy carbon anode, and FTO anode, wherein the PSII complexes are deposited onto the anode; (c) a source of red or white light, wherein red or white light illumination of the PSII complexes deposited on the anode generates a photoresponse comprising a photocurrent; (d) a working solution; and (e) a cathode; wherein the photoresponse remains stable for at least about 4 hours under intermittent illumination.

Further embodiments provide a system for generating hydrogen comprising: (a) isolated biological photosystem II (PSII) complexes; (b) an anode selected from the group consisting of a graphite anode, a glassy carbon anode, and an FTO anode, wherein the PSII complexes are deposited onto the anode; (c) a source of red or white light, wherein red or white light illumination of the PSII complexes deposited on the anode generates a photoresponse comprising a photocurrent; (d) a working solution; and (e) a platinum RRDE cathode; wherein the photocurrent from PS II is used to generate hydrogen production on the cathode.

Still further embodiments provide methods for generating photocurrent comprising: (a) isolating biological photosystem II (PSII) complexes; (b) providing an anode selected from the group consisting of a graphite anode, a glassy carbon anode, and an FTO anode, wherein the PSII complexes are deposited onto the anode; (c) providing a working solution; (d) providing a cathode; and (e) illuminating with red or white light the PSII complexes deposited on the anode, wherein red or white light illumination of PS II complexes generates a photoresponse comprising a photocurrent; wherein the photoresponse remains stable for at least about 4 hours under intermittent illumination.

Other embodiments provide methods for generating hydrogen comprising: (a) isolating biological photosystem II (PS II) complexes; (b) providing an anode selected from the group consisting of a graphite anode, a glassy carbon anode, and an FTO anode, wherein the PSII complexes are deposited onto the anode; (c) providing a working solution; (d) providing a platinum RRDE cathode; and (e) illuminating the PS II complexes deposited on the anode with red or white light, wherein illumination of the PS II complexes generates a photoresponse comprising a photocurrent and wherein the photocurrent from PS II is used to generate hydrogen production on the cathode.

In addition to the exemplary aspects and embodiments described above, further aspects and embodiments will become apparent by reference to the drawings and by study of the following descriptions.

### BRIEF DESCRIPTION OF THE DRAWINGS

FIG. 1 illustrates the effect of a soluble electron mediator on photocurrent generated by the PS II electrode. (1)—no mediator added; (2)—DMBQ added to a final concentration of 60 μM. Amperometric measurements were recorded at a +0.4V oxidizing potential versus Ag/AgCl electrode; a platinum electrode was used as the counter electrode. Photocurrent was initiated by illumination of the sample with red light (660 nm) for 10 s with a 40 s dark period for a total of 200 s.

FIG. 2 demonstrates the effect of different oxidizing potentials applied to the PS II electrode on the generated photocurrent. Amperometric measurements were recorded at oxidizing potentials of 0.1 V (1), 0.4 V (2), 0.6 V (3), and 0.8 V (4) versus Ag/AgCl electrode; a platinum electrode was used as the counter electrode. Photocurrent was initiated by illumination of the sample with red light (660 nm) for 10 s with a 40 s dark period for a total of 200 s.

FIG. 3 demonstrates the photocurrent generated on the PS II electrode as a function of illumination time. Amperometric measurements were recorded at +0.4V oxidizing potential applied to the PS II electrode versus Ag/AgCl electrode; a platinum electrode was used as the counter electrode. Photocurrent was initiated by illumination of the sample with red light (660 nm) for 10 s with a 40 s dark period for a total of 200 s (trace 1) or for 120 s with a 30 s dark period (trace 2).

FIG. 4 shows photocurrent as a function of concentration of electron mediator, DMBQ, in the working solution. Amperometric measurements were recorded at +0.4V oxidizing potential versus Ag/AgCl electrode; a platinum electrode was used as the counter electrode. Photocurrent was initiated by illumination of the sample with red light (660 nm) for 10 s with a 40 s dark period for a total of 200 s.

FIG. 5 illustrates the relationship between the photocurrent generated by the PS II electrode and the magnitude of the oxidizing potential applied to the electrode at 12.5 μM DMBQ (1) and 62.5 μM DMBQ (2) in the working solution (20 M MES, 80 mM NaCl). Ag/AgCl was used as the reference electrode and platinum as the counter electrode. The photocurrent was initiated by illumination of the sample with red light (660 nm) for 10 s with a 40 s dark period for a total of 300 s. Arbitrarily, the amplitudes of the third peak of photocurrent from each recorded trace were compared.

FIG. 6 shows amperometric curves recorded in the presence of 0 μM (1), 5 μM (2), and 10 μM (3) DCMU in the working solution. The working electrode was the PS II electrode. Platinum was used as the counter electrode, and Ag/AgCl as the reference electrode. Photocurrent was initiated by illumination of the sample with red light (660 nm) for 10 s with a 40 s dark period for a total of 200 s.

FIG. 7 shows amperometric curves recorded in the presence of 10 μM DCMU in the working solution and applied oxidizing potentials of +0.2 V (1), +0.4 V (2), +0.6 V (3), +0.8 V (4), and +1.0 V (5). The working electrode was the PS II electrode. Platinum was used as the counter electrode and Ag/AgCl as the reference electrode. The reaction was induced by illumination of the sample with red light (660 nm) for 10 s with a 40 s dark period for a total of 200 s.

FIG. 8 provides the action spectrum of the PS II electrode (solid line) concurrently with the absorption spectrum of the PSII electrode (dotted line). The dependence of the photocurrent on wavelength was recorded between 400 and 725 nm in 4 nm steps.

FIG. 9 illustrates the photocurrent generated on the PS II electrode in the presence of 60 μM DMBQ with an applied oxidizing potential of +0.9 V relative to the Pt disc electrode (A). The photocurrent was initiated by illumination of the sample with white light for 10 s with a 40 s dark period for a total of 200 s. The rotating disc of a platinum rotating ring disc electrode (RRDE) was wired to the PS II electrode (with +0.9 V bias), and the presumed hydrogen product was detected on the platinum ring electrode (B) with an applied potential of −0.1V vs Ag/AgCl. Illumination of the PS II electrode was initiated after this potential, sufficient to oxidize the hydrogen product, was applied to the platinum ring electrode for 300 s.

FIG. 10 illustrates two-chamber electrode system for concomitant light-induced PSII-dependent water oxidation and hydrogen production.

FIG. 11 demonstrates photocurrent generated on PS II electrode in the presence of 60 μM DMBQ and applied oxidizing potential of +1.0 V when previously frozen PS II sample (A) or freshly isolated PS II sample (B) were used. Photocurrent was initiated by illumination of the sample with white light for 10 s with a 40 s dark period for 200 s and 150 s respectively. Exemplary embodiments are illustrated in referenced figures of the drawings. It is intended that the embodiments and figures disclosed herein are to be considered illustrative rather than limiting.

### DETAILED DESCRIPTION

Provided herein are photocurrent-producing systems useful in generating hydrogen. The PS II electrode embodiments described herein are active, stable, and reliable for electrochemical work. Certain embodiments can be based upon the benefits of using isolated wild type PS II rather than genetically modified PS II to construct the electrode. Surprisingly, the use of wild type PS II or PS II in its native structure can provide an electrode with improved stability relative to recombinant or genetically modified PS II electrodes. Use of isolated PS II generates a more stable system relative to genetically modified PS II which is His-tagged and requires a heavy metal ion (Ni²⁺) to bind the PS II to an electrode. While not wishing to be bound by theory, it is believed the Ni²⁺ negatively impacts protein stability and hence the stability of a photocurrent-producing system. Natural membranes containing PS II are likewise less desirable in a photocurrent generating system as the lipid membranes act as insulators, preventing photocurrent flow.

In some instances, the preparation of the PS II electrode is less expensive or time-consuming relative to electrodes based on recombinant PS II. In further embodiments, the PS II electrode is constructed using inexpensive electrode materials. In some instances, the material of this electrode is any inexpensive alternative to gold, such as, for example, glassy carbon, FTO (fluorine-doped tin oxide), or pyrolytic graphite, as the surface of the electrode need not be chemically modified.

### Definitions

The following definitions are provided to facilitate understanding of certain terms.

The phrase “PS II complex” as used herein includes a reaction center and more than 16 subunits as well as other associated light harvesting proteins. The phrase “isolated PS II complexes” as used herein describes those PS II and associated proteins which are isolated from the photosynthetic membranes of living organisms as opposed to the PS II complexes that are embedded in the native photosynthetic membranes (thylakoids).

The phrase “intermittent illumination” refers to the cycle of illumination of the PS II followed by a period of darkness.

The abbreviation “DMBQ” refers to 2,6-dimethyl 1,4-benzoquinone. The abbreviation “DCBQ” refers to 2,6-dichloro-p-benzoquinone.

### Photosystem II

Photosystems are multiprotein complexes contained within the thylakoid membranes of plants, algae, and cyanobacteria. The pigments associated with Photosystem II (PS II) absorb light and transfer it to the reaction center (RC), thus generating a charge-separated state. Primary electron acceptors trap the resulting high-energy electrons, while the resulting hole (or electron deficit) is addressed by oxidation of water in the oxygen evolving complex. This process generates O₂ gas and protons. The energized electrons are transferred through various coenzymes and cofactors to reduce plastoquinone to plastoquinol.

The RC is at the heart of the PS II complex and consists of two homologous proteins known as D1 and D2. These proteins each have five transmembrane α-helices and bind cofactors facilitating primary charge separation. Two structurally homologous chlorophyll-containing proteins, CP43 and CP47, are associated with the D1 and D2 proteins and have six transmembrane α-helices with large extrinsic loops joining the luminal ends of the transmembrane α-helices V and VI. Other PS II complex subunits include several low-molecular weight proteins having a single transmembrane helix, including PsbE and PsbF which provide histidine ligands for the high potential heme of cytochrome b₅₅₉. Several extrinsic proteins attached to the luminal surface of the PS II RC form a protein shield over the catalytic site of water splitting, a unit which constitutes the PSII core complex.

### Photosystem II Electrode Preparation

As further described in the examples below, isolated PS II complexes are deposited on an electrode (the anode). PS II complexes can be isolated by any number of methods known to those skilled in the art, however an illustrative method is described by Schatz and Witt (Schatz, G. H. and H. T. Witt (1984) Extraction and characterisation of oxygen-evolving Photosystem II complexes from a thermophilic cyanobacterium Synechococcus sp. Photobiochem. Photobiophys. 7: 1-14) and are incorporated herein by reference. Isolated PS II complexes can be obtained from any photosynthetic organism performing oxygenic photosynthesis. In some embodiments, PS II complexes are isolated from plants. In other embodiments, PS II complexes are isolated from algae. In still other embodiments, PS II complexes are isolated from cyanobacteria such as, for example, thermophilic cyanobacteria. An exemplary thermophilic cyanobacteria is Thermosynechococcus elongatus. In some embodiments, the isolated PS II is stored by freezing and thawed prior to use. In other embodiments, PS II is freshly isolated just prior to use.

Isolated PS II complex is deposited on the electrode and allowed to adhere to the electrode by drying. In some embodiments, the complex is deposited on the electrode and dried in complete darkness overnight. Before using, the electrode surface containing the dried PS II sample is covered by a dialysis membrane secured to the electrode. The dialysis membrane prevents PS II from leaking into the working solution; it can be substituted with any other membrane, for example, any membrane having a similar molecular weight cutoff. The membrane can be secured with an o-ring.

Various types of electrodes are contemplated herein, including, for example, pyrolytic graphite edge electrodes, FTO electrodes, or glassy carbon electrodes. However, any electrode is useful herein where the electrode surface is not chemically modified. Electrodes with unmodified surfaces are, in some aspects, advantageous as they cost less than electrodes with chemically modified surfaces and because chemical modification can reduce the lifetime of the PS II deposited on the electrode.

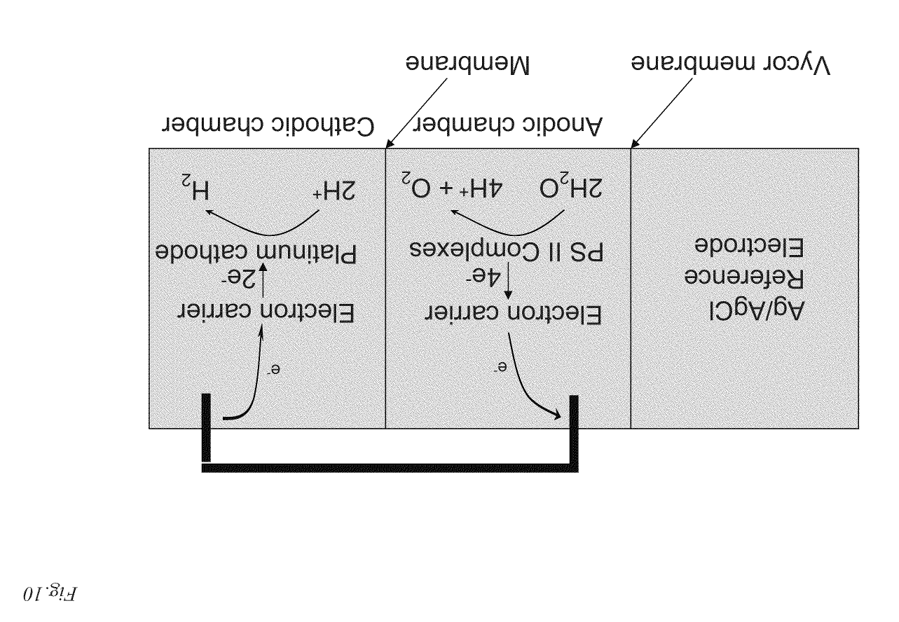

FIG. 10 is an illustrative embodiment of the photocurrent generating system described herein. A PS II anode is placed in the anodic chamber and a cathode in the cathodic chamber. Upon illumination, water is oxidized and releases O₂ and H⁺ in the anodic chamber. A power supply provides an additional oxidizing potential to the PS II electrode, and carries electrons from the anodic chamber to the cathodic chamber.

Electron mediators can be used to facilitate the transfer of electrons from PS II to the electrode surface. Exemplary electron mediators include, but are not limited to 1,4-benzoquinone (BQ), 2,6-dichloro-p-benzoquinone (DCBQ), and 2,6-dimethyl-1,4-benzoquinone (DMBQ). The electron mediator is added to the working solution. The chemical make-up of working solutions for such systems are known to those skilled in the art. An exemplary working solution has a pH of around 6.5 and contains 20 mM MES (2-(N-morpholino)ethanesulfonic acid) and 80 mM NaCl.

Separated from the PS II electrode (the working electrode) and the working solution is the counter electrode or cathode. In some embodiments, a vycor membrane separates the two electrodes. The counter electrode can be platinum, and in some embodiments, platinum mesh.

Also separated from the PS II electrode and the working solution is a reference electrode. As with the other electrodes, the reference electrode can be made of various materials, such as, for example, Ag/AgCl in saturated KCl or a saturated calomel electrode (Hg/Hg₂Cl₂ in saturated KCl).

Various methods of separating the electrodes are known to those skilled in the art. In some embodiments, the electrodes are separated by a vycor membrane. The vycor membrane is permeable to small ions and molecules, allowing protons to move from an anodic working solution to cathodic working solution where they are reduced to molecular hydrogen. Other membranes having similar properties are known to those skilled in the art and contemplated herein.

To run the system, an oxidizing potential can be applied to the PS II electrode using a power supply. In some embodiments, the oxidizing potential is between about 0.1 V and 1.0 V, but can be optimized for each system depending on the concentration of the electron mediator and other variables.

A photosystem is characterized by the wavelength of light to which it is most responsive, for example, PS II absorption spectrum peaks at a wavelength of 680 nm, the red part of the spectrum. Here, to generate a photocurrent, the PS II electrode is illuminated using a red LED or white LED. In some embodiments, the red LED has λₘₐₓ=660 nm. A pulsating cycle of light and dark, otherwise known as intermittent illumination, can be utilized to optimize the photocurrent. For example, PS II can be subjected to a cycle of 10 seconds of light and 40 seconds of dark, or a cycle of 120 seconds of light and 30 seconds of dark. Other cycle variations are contemplated, including, for example, 600 seconds of light followed by a 30 second dark period. Surprisingly, the PS II electrode is stable over several hours, and is in working condition the following day after storage in darkness at 4° C. overnight. In some embodiments, the electrode is stable under intermittent illumination for at least about 4 hours, for at least about 5 hours, for at least about 6 hours, for at least about 7 hours, for at least about 8 hours, for at least about 12 hours, or for at least about 24 hours.

### Hydrogen Production System

In some embodiments, the hydrogen production system has a PS II anode and a platinum cathode, a two-electrode configuration. In order to measure a cathodic response of this system (which corresponds to hydrogen production), the rotating ring disc electrode (RRDE) can be used. The disc of the RRDE can serve as a cathode in a hydrogen production circuit whereas the ring of the RRDE is used as a working electrode in a hydrogen detection circuit. The hydrogen detection circuit can have a three-electrode configuration with, for example, platinum mesh as a cathode and Ag/AgCl as a reference electrode. The RRDE is rotated such that hydrogen produced at the disc will be swept across the ring and detected as an anodic current. The RRDE connects both hydrogen producing and hydrogen measuring circuits.

The photocurrent-generating system described above can be used to produce hydrogen. In addition to the two-electrode photocurrent-generating system, there is a hydrogen detection system with a working electrode, a counter electrode, and a reference electrode. A potential sufficiently positive to oxidize molecular hydrogen, for example, about −0.1V, can be applied to the hydrogen detection circuit working electrode. One of skill in the art can optimize the potential according to various aspects of the system.

To run the system, an oxidizing potential is applied to the PS II electrode relative to the hydrogen producing cathode. Upon illumination of the thus poised PS II electrode and resulting photocurrent production, hydrogen is produced.

### EXAMPLES

The following examples are provided for illustrative purposes only and are not intended to limit the scope of the invention.

### Research Design and Methods

PS II complexes were isolated from Thermosynechococcus elongatus according to methods described by Schatz and Witt (1984, Extraction and characterisation of oxygen-evolving Photosystem II complexes from a thermophilic cyanobacterium Synechococcus sp. Photobiochem. Photobiophys. 7: 1-14) with modifications.

The PS II electrode was prepared by depositing 5 μl of 1 mM isolated PS II complex preparation onto the electrode in almost complete darkness, with a weak non-actinic green light present, and dried overnight at +4° C. in darkness. A pyrolytic graphite edge (PGE) electrode with a diameter of 4.8 mm or a glassy carbon (GC) electrode with a diameter of 3 mm was used. Directly before the experiment, the surface of the electrode containing dried PS II sample was covered with a dialysis membrane (12000-14000 MW cutoff) that was held in place by o-ring.

A 50 mM stock solution of DMBQ in ethanol was prepared fresh before the experiment and used as an electron mediator for PS II in various concentrations.

To study the effect of applied oxidizing potentials, DMBQ concentration, duration of illumination, quality of light, and time on the photocurrent generated by the PS II electrode, a PGE-PS II electrode was used as a working electrode, a platinum mesh (1 cm², separated from the working solution by a vycor membrane) as the counter electrode, and a freshly made Ag/AgCl in saturated KCl, separated from the working solution by a vycor membrane—as the reference electrode. The working solution (20 mM MES, 80 mM NaCl, pH 6.5) was deoxygenated before the experiments and thermostated at +4° C.

An oxidizing potential was applied to the PS II electrode using a CHI650C electrochemical station (CH Instrument, Inc., USA).

The photocurrent was generated by illumination of the PS II electrode by red LED (660 nm) or white LED. The following light/dark cycle was used: 10 s light, 40 s dark, unless specified otherwise.

The experiments in which the PS II electrode was tested by addition of DCMU were performed using the GC-PS II electrode, wired to a 4.8 mm diameter PGE-hydrogenase electrode. The hydrogenase electrode was prepared by soaking the PGE electrode for 75 minutes in a 1 ml of working solution (20 mM MES, 80 mM NaCl, pH 6.5) to which 30 μl of 0.2 mg/ml solution of purified [FeFe] hydrogenase from Clostridium acetobutylicum were added. The hydrogenase electrode was subsequently rinsed with deionized water. The PS II electrode and hydrogenase electrode were positioned in two compartments that were separated by a nafion membrane and filled up with the working solution cooled to +4° C. These experiments were conducted in a glove box under anaerobic atmospheric conditions (3.5% hydrogen, bulk—nitrogen, <1 ppm oxygen).

The PS II electrode action spectrum was recorded using a combination of a Xenon arc lamp and a monochromator as the light source. The intensity of monochromatic light reaching the PSII electrode was ˜1 mW cm⁻² at each wavelength investigated. Twenty ᵢll of PS II preparation were deposited onto the fluorine-doped tin oxide (FTO) electrode with a surface area of 1.33 cm² and dried at +4° C. overnight in darkness. Directly before the experiment, the PS II film on the FTO was covered with dialysis membrane (12000-14000 MW cutoff) that was held in place by an o-ring. The FTO-PS II electrode was positioned in an anode compartment of teflon cell and separated from a cathode compartment by a nafion membrane. A platinum mesh electrode was used as the cathode and a freshly made Ag/AgCl in saturated KCl as the reference electrode. The working solution (20 mM MES, 80 mM NaCl, pH 6.5) was deoxygenated and cooled to +4° C. The working solution in the anode compartment contained 285 μM DMBQ as the electron mediator. The action spectrum was recorded upon the application of an oxidizing potential of +0.4 V.

To demonstrate that the PS II electrode can be used for hydrogen production, a GC-PS II electrode was prepared as described above (electrode diameter: 3 mm; 5 μl of PS II preparation). Directly before the experiment, the PS II film on the electrode surface was covered with a dialysis membrane (12000-14000 MW cutoff) that was held in place by an o-ring. This PS II electrode was used as an anode in a hydrogen production circuit (the platinum disc of a RRDE was used as the cathode). The electrodes were immersed in the working solution (20 mM MES, 80 mM NaCl, pH 6.5) that was deoxygenated and cooled to +4° C. Sixty μM DMBQ was added to the working solution as the electron mediator. The photocurrent was initiated by illumination of the sample with white light for 10 s with a 40 s dark period for 200 s. An oxidizing potential of +0.9 V was applied to the PS II electrode using a K2400 electrochemical station (Keithley Instruments, USA). In the hydrogen detection circuit, the platinum ring in the rotating ring disc electrode (RRDE) was used as the working electrode, platinum foil (1 cm²) was the counter electrode, and a Ag/AgCl in saturated KCl solution as the reference electrode. A potential of −0.1V vs Ag/AgCl applied to the ring of the RRDE by the CHI650C electrochemical station was found optimal for hydrogen detection. During this experiment, the RRDE was rotated at 1000 rpm, and a constant flow of argon was maintained above the working solution.

### Results

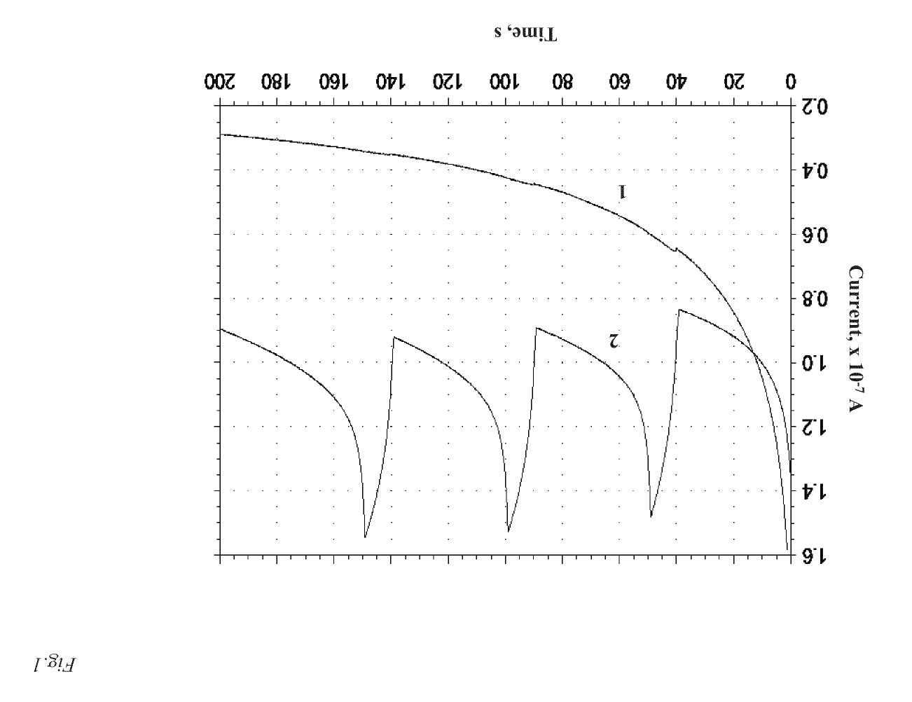

Since PS II particles are deposited in random orientation on the surface of the PS II electrode, it was expected that the direct, mediatorless electron transfer from the PS II to the electrode would be negligible, and an electron mediator would be necessary to facilitate the photoresponse of the PS II electrode. Indeed, addition of DMBQ to the working solution dramatically improved the amplitude of photocurrent generated by the PS II electrode (FIG. 1). Therefore, DMBQ presence was beneficial for electron transfer from the PS II complexes to the electrode and accompanying generation of photocurrent.

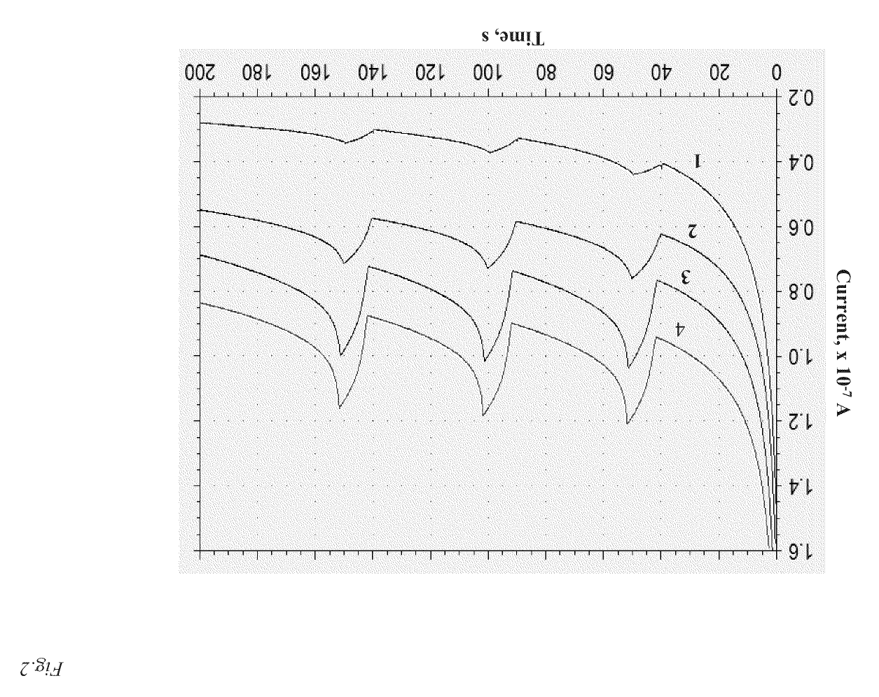

The magnitude of the oxidizing potential applied to the PS II electrode had a dramatic effect on the amplitude of the generated photocurrent (FIG. 2). However, increases in the applied oxidizing potential above +0.6 V versus Ag/AgCl did not improve the photocurrent, but rather had an inhibitory effect.

Light quality slightly affected the resulting photocurrent: white light produced a photocurrent of amplitude about 21% greater than red light of the same intensity (1.17±0.04×10⁻⁷ A versus 0.97±0.01×10⁻⁷ A in the presence of 285 μM DMBQ in the working solution and an applied oxidizing potential of +0.4 V vs Ag/AgCl).

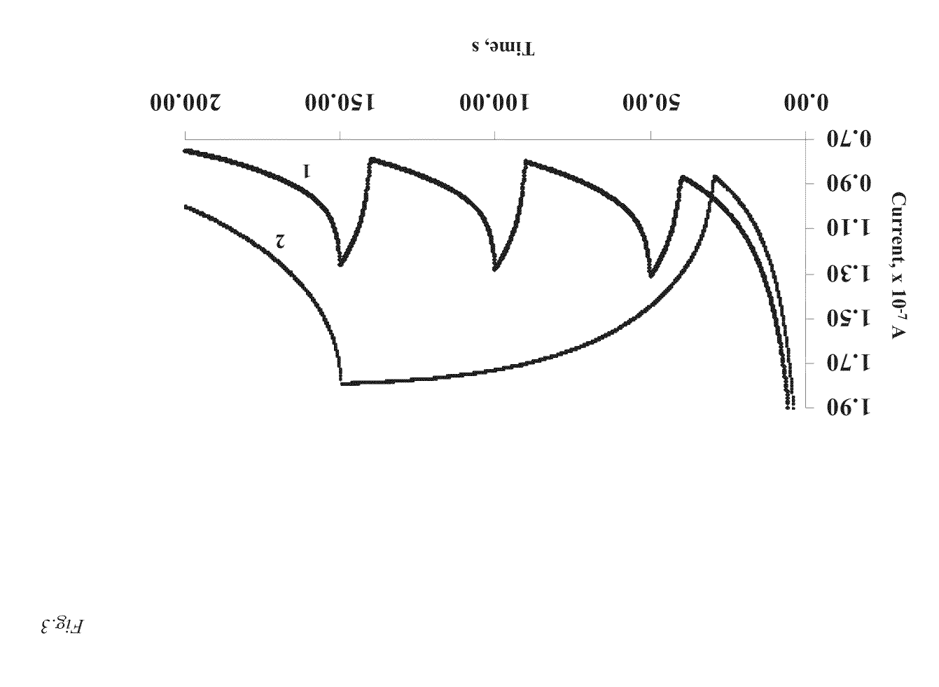

The length of light/dark period had an effect on current generated by the PS II electrode: increases in the light period for up to at least 120 s of continuous illumination resulted in increases in the amplitude of the photocurrent (FIG. 3).

The photoresponse of the PS II electrode was stable during the entire length of the experiment (6 hours), and the electrode was still in working order the next day, albeit with the amplitude of the response down to about one third of the original (Table 1).

TABLE 1
Photocurrent generated on the PS II electrode as a function of time.

| Time, h | Photocurrent, ×10⁻⁷ A | | |
|---|---|---|---|
| 0-6^{a} | 17.5 ± 2.2 | 14.0 ± 2.6 | 12.7 ± 1.5 |
| 0^{b} | 8.4 ± 0.8 | | |
| 24^{b} | 2.8 ± 0.4 | | |

^{a}Measurements were taken within first 6 h of the experiment in the presence of 12.5 μM DMBQ in the working solution and illumination with red light (10 s light, 40 s dark period) for 200 s.
^{b}Recorded at oxidizing potential of 0.1 V applied to the PS II electrode and illumination with red light (10 s light, 40 s dark period) for 200 s. DMBQ was added to the working solution in final concentration of 62.5 μM.

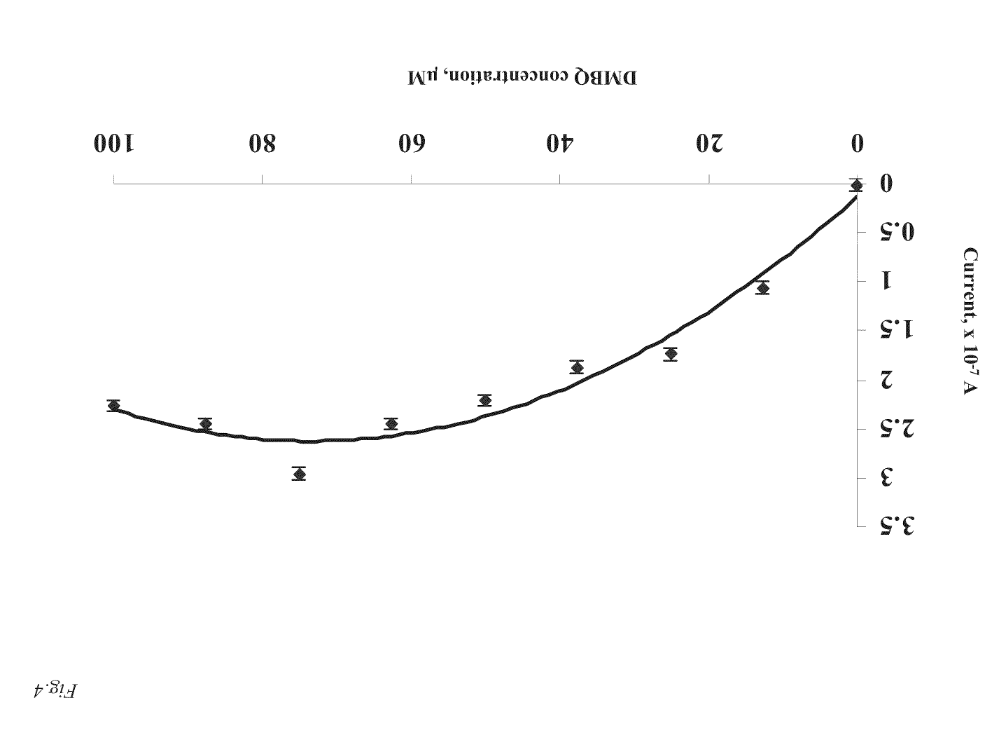

The concentration of the electron mediator, DMBQ, determined the amplitude of photocurrent generated by the PS II electrode. The photocurrent increased with an increase in DMBQ concentration up to 80 μM. Further increases in DMBQ concentration had an inhibitory effect on the photocurrent (FIG. 4). The concentration of the electron mediator (DMBQ) is proportional to the amount of electron donor (PS II); therefore, to reach maximum photocurrent at higher PS II concentration, more electron mediator will be required.

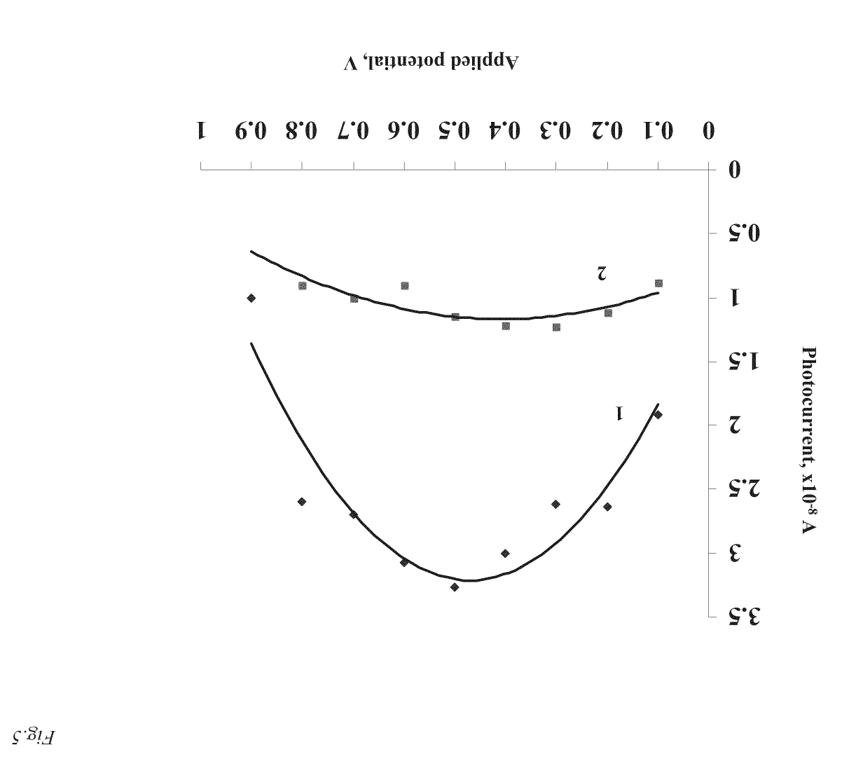

Increases in the oxidizing potential applied to the PS II electrode up to +0.5 V versus Ag/AgCl had a positive effect on the magnitude of photocurrent generated, regardless of whether low or medium concentration of DMBQ was used to transfer electrons from the PS II to the electrode (FIG. 5). However, further increases in the applied oxidizing potential diminished the efficiency of the PS II electrode.

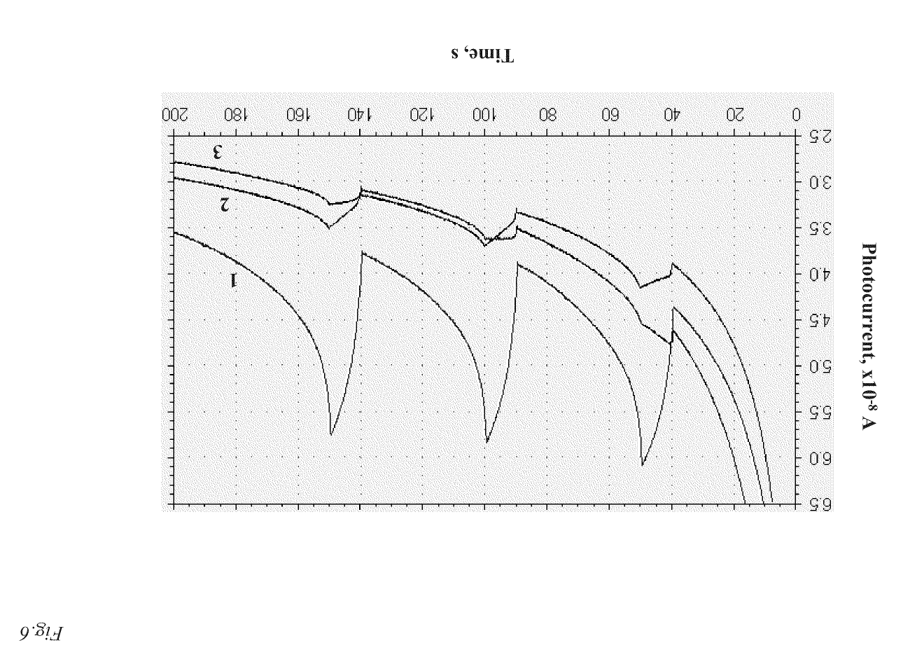

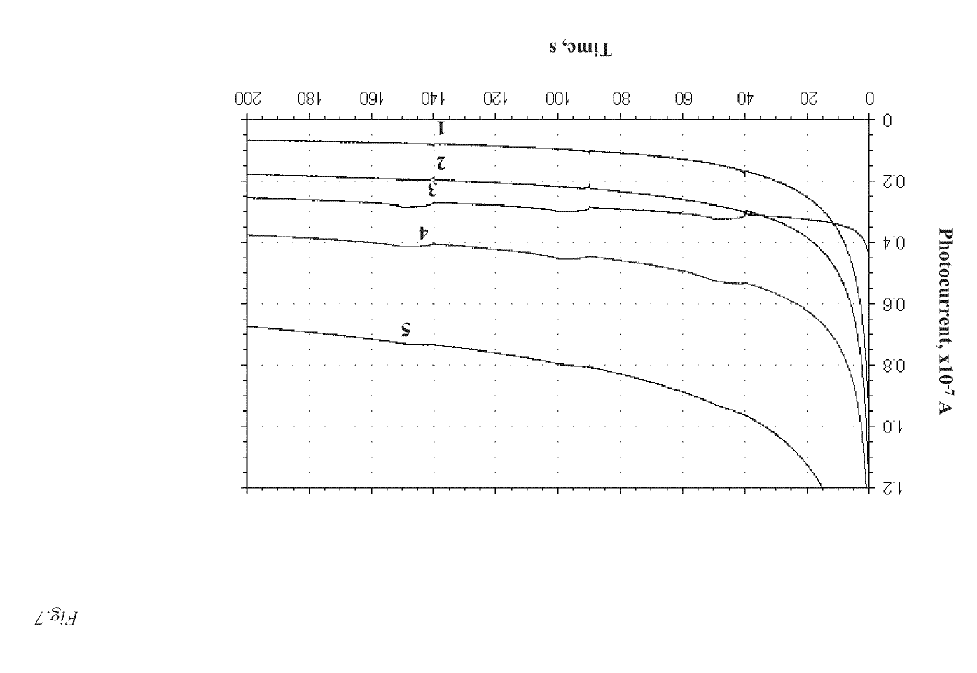

DCMU, an inhibitor of electron transfer within PS II, inhibited the generation of photocurrent by the PS II electrode (FIG. 6). This phenomenon was observed at all values of oxidizing potential tested (FIG. 7), and demonstrates that the redox activity of the PS II deposited on the electrode is the source of the photocurrent observed in the experiments.

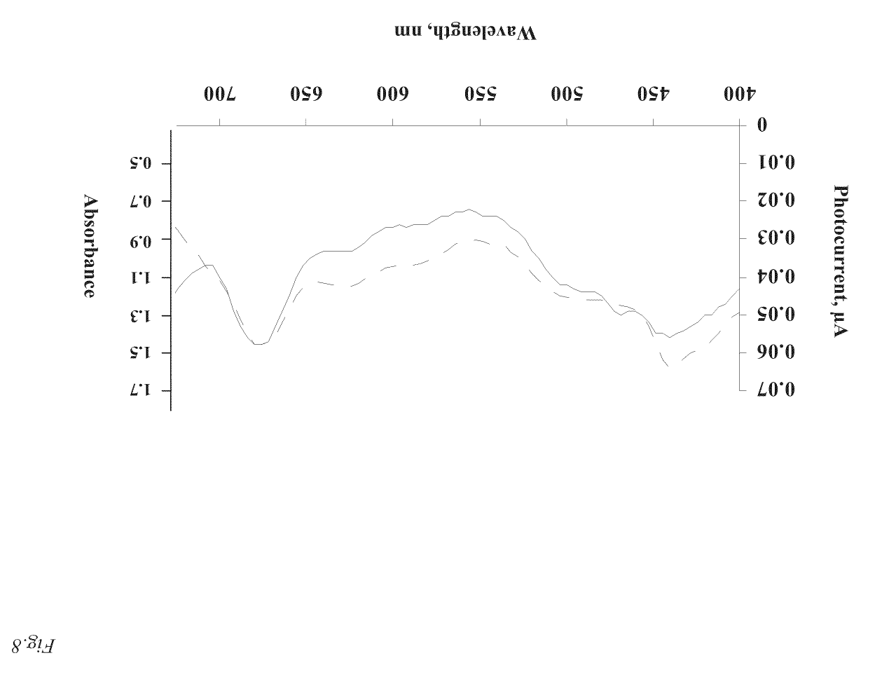

The action spectrum of the PS II electrode is similar to the absorption spectrum of the PS II deposited on the electrode (FIG. 8). This demonstrates that the chlorophyll pigments within PS II were the light absorbing species giving rise to photocurrent.

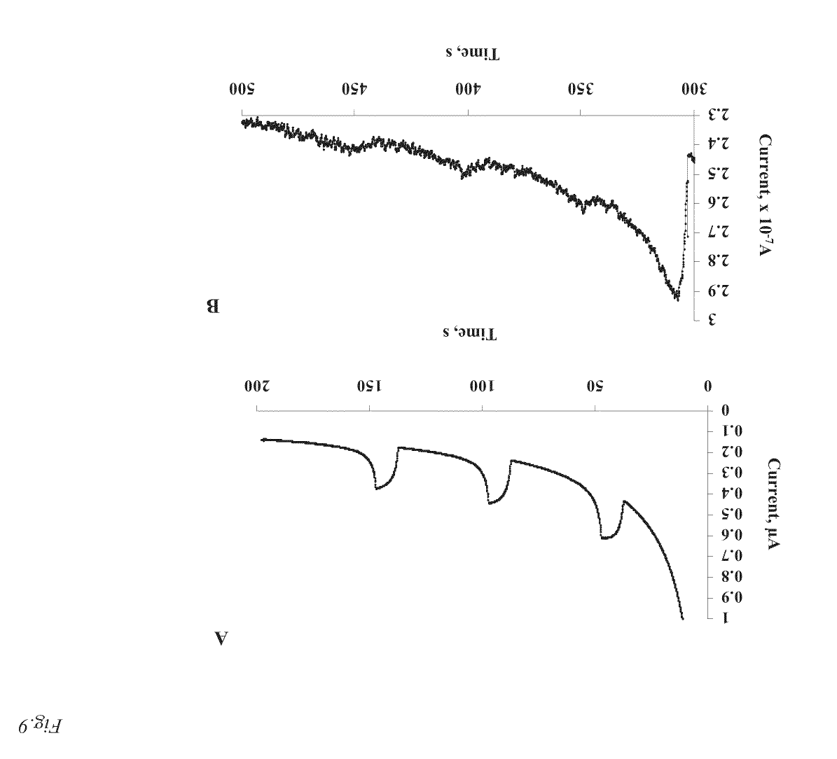

When the PS II electrode was connected to a platinum RRDE (rotating ring disc electrode) in a two circuit setup (a hydrogen production circuit, consisting of the PS II electrode and the disc of the RRDE, and a hydrogen detection circuit, consisting of the ring of the RRDE as a working electrode, platinum foil as a counter electrode, and Ag/AgCl as a reference electrode) and an oxidizing potential of +0.9 V was applied to the PS II electrode relative to the Pt disc, hydrogen production was detected in response to photocurrent (FIG. 9). This proved the usefulness of the PS II electrode in electrochemical production of hydrogen using light-driven water oxidation.

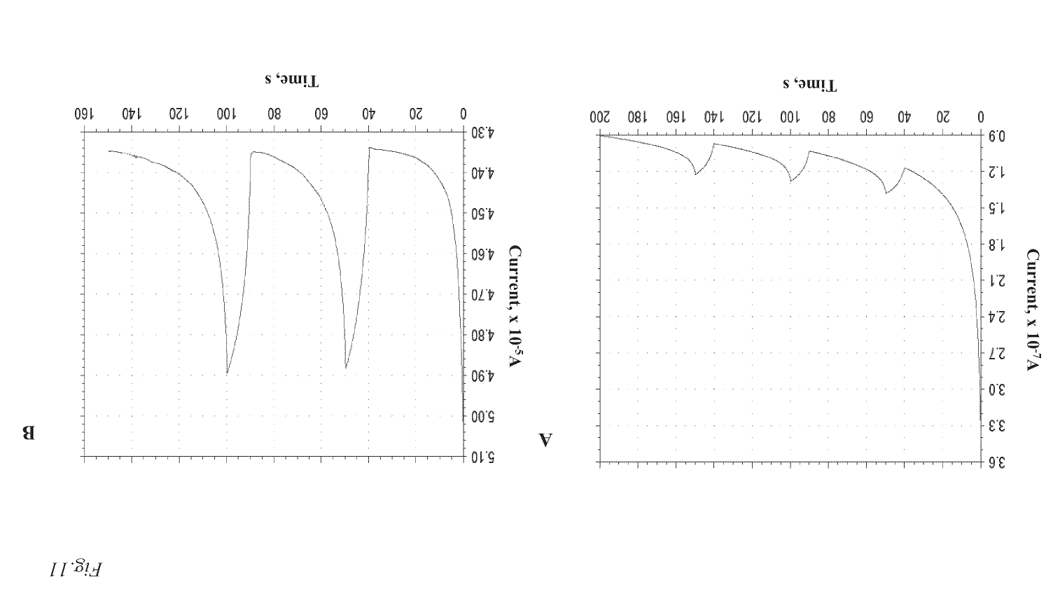

Freshly isolated PS II complexes demonstrated a substantially higher photocurrent than those that were frozen upon isolation and thawed before being used in the experiments (FIG. 11).

A number of patents, patent application publications, and scientific publications are cited throughout and/or listed at the end of the description. Each of these is incorporated herein by reference in their entirety. Likewise, all publications mentioned in an incorporated publication are incorporated by reference in their entirety.

Examples in cited publications and limitations related therewith are intended to be illustrative and not exclusive. Other limitations of the cited publications will become apparent to those of skill in the art upon a reading of the specification and a study of the drawings.

The words “comprise”, “comprises”, and “comprising” are to be interpreted inclusively rather than exclusively.

While a number of exemplary aspects and embodiments have been discussed above, those of skill in the art will recognize certain modifications, permutations, additions and sub-combinations thereof. It is therefore intended that the following appended claims and claims hereafter introduced are interpreted to include all such modifications, permutations, additions and sub-combinations as are within their true spirit and scope.

What is claimed is:

1. A system for generating photocurrent, the system comprising:
(a) isolated biological photosystem II (PSII) complexes;
(b) an anode selected from the group consisting of graphite anode, glassy carbon anode, and FTO anode, wherein the PSII complexes are deposited onto the anode;
(c) a source of red or white light, wherein red or white light illumination of the PSII complexes deposited on the anode generates a photoresponse comprising a photocurrent;
(d) a working solution; and
(e) a cathode;
wherein the photoresponse remains stable for at least about 4 hours under intermittent illumination.

2. The system of claim 1 further comprising an electron mediator in the working solution, wherein the electron mediator is selected from the group consisting of 2,6-dimethylbenzoquinone (DMBQ), 2,6-dichloro-p-benzoquinone (DCBM), and 1,4-benzoquinone (BQ).

3. The system of claim 2, wherein the electron mediator is DMBQ and the concentration of DMBQ is from at least about 5 μM to at least about 145 μM in the working solution.

4. The system of claim 1, wherein the PSII complexes are isolated from a thermophilic cyanobacterium.

5. The system of claim 1, wherein the PS II complexes are freshly isolated.

6. The system of claim 4, wherein the thermophilic cyanobacterium is Thermosynechococcus elongatus.

7. The system of claim 1 further comprising a power supply capable of applying an oxidizing potential to the anode.

8. The system of claim 1, wherein the cathode comprises platinum mesh or platinum foil.

9. The system of claim 1, wherein the cathode comprises a rotating ring disc electrode (RRDE).

10. A system for generating hydrogen, the system comprising:
(a) isolated biological photosystem II (PSII) complexes;
(b) an anode selected from the group consisting of a graphite anode, a glassy carbon anode, and an FTO anode, wherein the PSII complexes are deposited onto the anode;
(c) a source of red or white light, wherein red or white light illumination of the PSII complexes deposited on the anode generates a photoresponse comprising a photocurrent;
(d) a working solution; and
(e) a platinum RRDE cathode;
wherein the photocurrent from PS II is used to generate hydrogen production on the cathode.

11. A method for generating photocurrent, the method comprising:
(a) isolating biological photosystem II (PSII) complexes;
(b) providing an anode selected from the group consisting of a graphite anode, a glassy carbon anode, and an FTO anode, wherein the PSII complexes are deposited onto the anode;
(c) providing a working solution;
(d) providing a cathode; and
(e) illuminating with red or white light the PSII complexes deposited on the anode, wherein red or white light illumination of PS II complexes generates a photoresponse comprising a photocurrent;
wherein the photoresponse remains stable for at least about 4 hours under intermittent illumination.

12. The method of claim 11 further comprising an electron mediator in the working solution, wherein the electron mediator is selected from the group consisting of 2,6-dimethylbenzoquinone (DMBQ) and 1,4-benzoquinone (BQ).

13. The method of claim 12, wherein the electron mediator is DMBQ and the concentration of DMBQ is from at least about 5 μM to at least about 145 μM in the working solution.

14. The method of claim 11, wherein the PSII complexes are isolated from a thermophilic cyanobacterium.

15. The method of claim 12, wherein the thermophilic cyanobacterium is Thermosynechococcus elongatus.

16. The method of claim 11 further comprising providing an oxidizing potential to the anode.

17. The method of claim 16, wherein the oxidizing potential is at least about 0.1 V to at least about 1.0 V vs. Ag/AgCl.

18. The method of claim 11, wherein the cathode comprises platinum mesh or platinum foil.

19. The method of claim 11 further comprising a platinum RRDE.

20. A method for generating hydrogen, the system comprising:
(a) isolating biological photosystem II (PS II) complexes;
(b) providing an anode selected from the group consisting of a graphite anode, a glassy carbon anode, and an FTO anode, wherein the PSII complexes are deposited onto the anode;
(c) providing a working solution;
(d) providing a platinum RRDE cathode; and
(e) illuminating the PS II complexes deposited on the anode with red or white light,
wherein illumination of the PS II complexes generates a photoresponse comprising a photocurrent and wherein the photocurrent from PS II is used to generate hydrogen production on the cathode.
